(19) United States
(12) Patent Application Publication
(10) Pub. No.: US 2017/0365733 A1
(43) Pub. Date: Dec. 21, 2017

(54) METHOD FOR PRODUCING DOPED POLYCRYSTALLINE SEMICONDUCTOR LAYERS

(71) Applicants: Christoph MADER, Muenster (DE); Odo WUNNICKE, Muenster (DE); Susanne MARTENS, Loerrach (DE); Jasmin LEHMKUHL, Haltern am See (DE); Christian GUENTHER, Wuppertal (DE)

(72) Inventors: Christoph MADER, Muenster (DE); Odo WUNNICKE, Muenster (DE); Susanne MARTENS, Loerrach (DE); Jasmin LEHMKUHL, Haltern am See (DE); Christian GUENTHER, Wuppertal (DE)

(73) Assignee: Evonik Degussa GmbH, Essen (DE)

(21) Appl. No.: 15/527,586

(22) PCT Filed: Nov. 17, 2015
(86) PCT No.: PCT/EP2015/076761

§ 371 Date: May 17, 2017

(30) Foreign Application Priority Data
Nov. 18, 2014 (DE) 10 2014 223 465.4

(51) Int. Cl. H01L 31/18; H01L 31/0368; H01L 31/0288; B05D 3/02; H01L 31/0745; B05D 1/00

(52) U.S. Cl. CPC H01L 31/182; H01L 31/1872; H01L 31/0745; B05D 1/005; H01L 31/0288; B05D 3/0254; H01L 31/03682

(57) ABSTRACT

The present invention relates to a method for producing highly doped polycrystalline semiconductor layers on a semiconductor substrate, wherein a first Si precursor composition comprising at least one first dopant is applied to one or more regions of the surface of the semiconductor substrate; optionally a second Si precursor composition comprising at least one second dopant is applied to one or more other regions of the surface of the semiconductor substrate, where the first dopant is an n-type dopant and the second dopant is a p-type dopant or vice versa; and the coated regions of the surface of the semiconductor substrate are each converted, so as to form polycrystalline silicon from the Si precursor. The invention further relates to the semiconductor obtainable by the method and to the use thereof, especially in the production of solar cells.

The present invention relates to a method for producing doped polycrystalline semiconductor layers on a semiconductor substrate, to the semiconductors obtainable by the method and to the use thereof, especially in solar cells.

Various applications require doped semiconductor layers, for example in photovoltaics. Photovoltaics is based on the generation of free charge carriers in a semiconductor by means of incident light. For electrical utilization of these charge carriers (separation of electrons and holes), a p-n junction in the semiconductor is required. Typically, silicon is used as the semiconductor. The silicon wafer used typically has base doping, for example with boron (p-type). Typically, the p-n junction is produced by inward diffusion of phosphorus (n-type dopant) from the gas phase at temperatures around 900° C. Both semiconductor types (p and n) are connected to metal contacts for extraction of the corresponding charge carriers.

However, the efficiency of solar cells based on such silicon wafers is frequently limited by the recombination of charge carriers at the contact between metal and semiconductor.

This recombination can be prevented, for example, by the use of amorphous silicon layers. But a disadvantage of amorphous silicon is low thermal stability, which does not permit the use of the standard processes for production of solar cells. Therefore, it is necessary to use specific adapted costly alternative methods, which increase the production costs for the solar cells.

A known alternative in the prior art is therefore to use an ultrathin oxide layer, on which is deposited a highly doped polysilicon layer. This strategy has the advantage that recombination at the metal-semiconductor contact is likewise significantly reduced as a result and the functionality of this layer is not altered even at temperatures of 1050° C. Typically, in such methods, oxides, usually silicon oxide, are deposited or grown onto the silicon wafer in a thickness of 1-4 nm. Deposited on these oxides in turn are then intrinsic amorphous silicon layers. The amorphous silicon layers are subsequently converted by means of a high-temperature step to polysilicon. Subsequently, the polysilicon is doped with phosphorus or boron in a further high-temperature step and in this way converted to n-type or p-type silicon. The amorphous silicon is typically deposited by means of chemical vapour deposition (CVD). A disadvantage in this case is the full-area deposition on both sides and resultant high process complexity for production of structured or single-sided layers. Thus, even in the case of single-sided deposition, simultaneous deposition at the substrate edge can lead, for example, to short circuits in the solar cell. Further disadvantages are high equipment costs for the CVD system and the high process complexity with several steps and long process times.

The problem addressed by the present invention is thus that of providing a method for producing doped polycrystalline semiconductor layers on a semiconductor substrate, especially a silicon wafer, which enables the disadvantages of known methods to be at least partly overcome.

The present problem is solved by the liquid-phase method according to the invention for producing doped polycrystalline semiconductor layers on a semiconductor substrate, especially a silicon wafer, in which
a first precursor composition comprising:
   (i) a first dopant; and
   (ii) at least one silicon-containing precursor which is liquid under SATP conditions or at least one solvent and at least one silicon-containing precursor which is liquid or solid under SATP conditions;
is applied to one or more regions of the surface of the semiconductor substrate, in order to create one or more region(s) of the surface of the semiconductor substrate coated with the first precursor composition;
optionally a second precursor composition comprising:
   (i) a second dopant; and
   (ii) at least one silicon-containing precursor which is liquid under SATP conditions or at least one solvent and at least one silicon-containing precursor which is liquid or solid under SATP conditions;
is applied to one or more regions of the surface of the semiconductor substrate, in order to create one or more region(s) of the surface of the semiconductor substrate coated with the second precursor composition, where the one or more region(s) coated with the first precursor composition and the one or more region(s) coated with the second precursor composition are different and do not overlap significantly, if at all, and where the first dopant is an n-type dopant and the second dopant is a p-type dopant or vice versa; and
the silicon-containing precursor is converted to polycrystalline silicon.

A liquid-phase method is understood in the present context to mean a method in which liquid silicon-containing precursors (functioning as solvents for the dopants and any further additives) or liquid solutions containing the silicon-containing precursors (themselves liquid or solid) and dopants (and any further additives) are applied as a wet film to the semiconductor. The silicon-containing precursors are then subsequently converted, for example by thermal means or with electromagnetic radiation, to an essentially elemental polycrystalline silicon coating. A “conversion” in the context of the present invention is therefore understood to mean the conversion of a precursor composition to said elemental polycrystalline silicon layer. This conversion can be effected in one stage, i.e. from the wet film to polycrystalline silicon, or else in two stages via an intermediate stage of amorphous silicon.

The p-type and n-type dopants may especially take the form of element compounds of main group III and V respectively. The at least one n-type dopant may be selected from phosphorus-containing dopants, especially PH₃, P₄, P(SiMe₃)₃, PhP(SiMe₃)₂, Cl₂P(SiMe₃), PPh₃, PMePh₂ and P(t-Bu)₃, arsenic-containing dopants, especially As(SiMe₃)₃, PhAs(SiMe₃)₂, Cl₂As(SiMe₃), AsPh₃, AsMePh₂, As(t-Bu)₃ and AsH₃, antimony-containing dopants, especially Sb(SiMe₃)₃, PhSb(SiMe₃)₂, Cl₂Sb(SiMe₃), SbPh₃, SbMePh₂ and Sb(t-Bu)₃, and mixtures of the above. The at least one p-type dopant may be selected from boron-containing dopants, especially B₂H₆, BH₃*THF, BEt₃, BMe₃, B(SiMe₃)₃, PhB(SiMe₃)₂, Cl₂B(SiMe₃), BPh₃, BMePh₂, and B(t-Bu)₃, and mixtures thereof.

“At least one” as used herein means 1 or more, i.e. 1, 2, 3, 4, 5, 6, 7, 8, 9 or more. Based on one constituent, the figure relates to the type of constituent and not to the absolute number of molecules. “At least one dopant” thus means, for example, at least one type of dopant, meaning that it is possible to use one type of dopant or a mixture of two or more different dopants. Together with stated amounts, the number relates to all the compounds of the specified type that are present in the composition/mixture, meaning that the composition does not contain any further compounds of this kind over and above the specified amount of corresponding compounds.

All percentages stated in connection with the compositions described herein relate, unless explicitly stated otherwise, to % by weight, based in each case on the corresponding composition.

“Roughly” or “about” as used herein in connection with a numerical value relates to the numerical value ±10%, preferably ±5%.

The converted semiconductor layers producible by the method according to the invention contain or consist of elemental silicon in polycrystalline form in combination with the particular dopant. In particular embodiments, the layers produced by the method according to the invention may be layers which, as well as elemental polycrystalline silicon and the particular dopant, also contain other constituents or elements. In this case, however, it is preferable that these additional constituents of the layer make up not more than 30% by weight, preferably not more than 15% by weight, based on the total weight of the layer.

In the methods according to the invention, the coatings with the first composition and with the second composition may be structured, a “structured” coating herein being understood to mean a coating which does not cover the substrate completely or essentially completely but covers the substrate partially to produce a structured pattern. Corresponding structured patterns can take on the task of solving technical problems, especially in semiconductor technology. Typical examples of structured layers are conductor tracks (for example for contact connections), finger structures or point structures (for example for emitter and base regions in back-contact solar cells) and selective emitter structures in solar cells.

In the methods of the invention, the first composition containing at least one first dopant and the second composition containing at least one second dopant are applied to different regions of the substrate surface that do not overlap or essentially do not overlap. “Essentially not overlapping” means here that the regions overlap over not more than 5% of their respective areas. It is preferable that the regions do not overlap at all, but such overlaps may occur as a result of the process. In that case, however, these are frequently unwanted. The application can in each case be effected in a structured manner, in such a way that the first composition and the second composition are applied to the surface of the silicon wafer, for example, on one side in an interdigitated structure, or the first composition and the second composition are each applied to the opposite sides of the silicon wafer.

The precursor compositions for the purposes of the present invention, i.e. the first and the optional second precursor composition, are especially understood to mean compositions which are liquid under SATP conditions (25° C., 1.013 bar), which either contain at least one silicon-containing precursor which is liquid under SATP conditions or contain or consist of at least one solvent and at least one silicon-containing precursor which is liquid or solid under SATP conditions, in each case in combination with the particular dopant. Particularly good results can be achieved with compositions comprising at least one solvent and at least one silicon-containing precursor which is liquid or solid under SATP conditions, in combination with the particular dopant, since these have particularly good printability.

The precursors generally include all suitable polysilanes, polysilazanes and polysiloxanes, especially polysilanes. Preferred silicon-containing precursors are silicon-containing compounds (which are especially liquid or solid under SATP conditions) of the formula SiₙX_{c} with X=H, F, Cl, Br, I, C₁-C₁₀-alkyl, C₁-C₁₀-alkenyl, C₅-C₂₀-aryl, n≧4 and 2n≦c≦2n+2. Likewise preferred silicon-containing precursors are silicon-containing nanoparticles.

Particularly good results can be obtained when a composition including at least two precursors is used, at least one of which is a hydridosilane, especially of the generic formula SiₙH₂ₙ₊₂ with n=3 to 20, especially 3 to 10, and at least one is a hydridosilane oligomer. Alternatively, it is also possible to use compositions containing only hydridosilane oligomer(s). Corresponding formulations are especially suitable for production of high-quality layers from the liquid phase, give good wetting of substrates that are standard in the coating operation and have sharp edges after structuring. The formulation is preferably liquid, since it can thus be handled in a particularly efficient manner.

Hydridosilanes of the formula SiₙH₂ₙ₊₂ with n=3 to 20 are noncyclic hydridosilanes. The isomers of these compounds may be linear or branched. Preferred noncyclic hydridosilanes are trisilane, isotetrasilane, n-pentasilane, 2-silyltetrasilane and neopentasilane, and also octasilane (i.e. n-octasilane, 2-silylheptasilane, 3-silylheptasilane, 4-silylheptasilane, 2,2-disilylhexasilane, 2,3-disilylhexasilane, 2,4-disilylhexasilane, 2,5-disilylhexasilane, 3,4-disilylhexasilane, 2,2,3-trisilylpentasilane, 2,3,4-trisilylpentasilane, 2,3,3-trisilylpentasilane, 2,2,4-trisilylpentasilane, 2,2,3,3-tetrasilyltetrasilane, 3-disilylhexasilane, 2-silyl-3-disilylpentasilane and 3-silyl-3-disilylpentasilane) and nonasilane (i.e. n-nonasilane, 2-silyloctasilane, 3-silyloctasilane, 4-silyloctasilane, 2,2-disilylheptasilane, 2,3-disilylheptasilane, 2,4-disilylheptasilane, 2,5-disilylheptasilane, 2,6-disilylheptasilane, 3,3-disilylheptasilane, 3,4-disilylheptasilane, 3,5-disilylheptasilane, 4,4-disilylheptasilane, 3-disilylheptasilane, 4-disilylheptasilane, 2,2,3-trisilylhexasilane, 2,2,4-trisilylhexasilane, 2,2,5-trisilylhexasilane, 2,3,3-trisilylhexasilane, 2,3,4-trisilylhexasilane, 2,3,5-trisilylhexasilane, 3,3,4-trisilylhexasilane, 3,3,5-trisilylhexasilane, 3-disilyl-2-silylhexasilane, 4-disilyl-2-silylhexasilane, 3-disilyl-3-silylhexasilane, 4-disilyl-3-silylhexasilane, 2,2,3,3-tetrasilylpentasilane, 2,2,3,4-tetrasilylpentasilane, 2,2,4,4-tetrasilylpentasilane, 2,3,3,4-tetrasilylpentasilane, 3-disilyl-2,2-disilylpentasilane, 3-disilyl-2,3-disilylpentasilane, 3-disilyl-2,4-disilylpentasilane and 3,3-disilylpentasilane), the formulations of which lead to particularly good results.

Likewise preferably, the hydridosilane of said generic formula is a branched hydridosilane which leads to more stable solutions and better layers than a linear hydridosilane.

Most preferably, the hydridosilane is isotetrasilane, 2-silyltetrasilane, neopentasilane or a mixture of nonasilane isomers, which can be prepared via thermal treatment of neopentasilane or by a method described by Holthausen et al. (poster presentation: A. Nadj, 6th European Silicon Days, 2012). The best results can be achieved with corresponding formulations.

The hydridosilane oligomer is the oligomer of a hydridosilane compound, and preferably the oligomer of a hydridosilane. The inventive formulation is of particularly good suitability when the hydridosilane oligomer has a weight-average molecular weight of 600 to 10 000 g/mol. Methods for preparation thereof are known to those skilled in the art. Corresponding molecular weights can be determined via gel permeation chromatography using a linear polystyrene column with cyclooctane as eluent against polybutadiene as reference, for example according to DIN 55672-1:2007-08.

The hydridosilane oligomer is preferably obtained by oligomerization of noncyclic hydridosilanes. Unlike hydridosilane oligomers formed from cyclic hydridosilanes, these oligomers have a high crosslinking level because of the different way in which the dissociative polymerization mechanism proceeds. Instead, because of the ring-opening reaction mechanism to which cyclic hydridosilanes are subject, oligomers formed from cyclic hydridosilanes have only a very low crosslinking level, if any. Corresponding oligomers prepared from noncyclic hydridosilanes, unlike oligomers formed from cyclic hydridosilanes, give good wetting of the substrate surface in solution and lead to homogeneous and smooth surfaces. Even better results are exhibited by oligomers formed from noncyclic branched hydridosilanes.

A particularly preferred hydridosilane oligomer is an oligomer obtainable by thermal conversion of a composition comprising at least one noncyclic hydridosilane having not more than 20 silicon atoms in the absence of a catalyst at temperatures of <235° C. Corresponding hydridosilane oligomers and the preparation thereof are described in WO 2011/104147 A1, to which reference is made with regard to the compounds and the preparation thereof, and which is incorporated herein in its entirety by virtue of this reference. This oligomer has even better properties than the further hydridosilane oligomers formed from noncyclic, branched hydridosilanes. The hydridosilane oligomer may also have other residues aside from hydrogen and silicon. Thus, advantages of the layers produced with the formulations may result when the oligomer contains carbon. Corresponding carbon-containing hydridosilane oligomers can be prepared by co-oligomerization of hydridosilanes with hydrocarbons. Preferably, however, the hydridosilane oligomer is a compound containing exclusively hydrogen and silicon, and which thus does not have any halogen or alkyl residues.

Preference is further given to hydridosilane oligomers which have already been doped. Preferably, the hydridosilane oligomers have been boron- or phosphorus-doped. Corresponding hydridosilane oligomers can be produced by adding the appropriate dopants at the early stage of the production thereof. Alternatively, it is also possible to p-dope or n-dope already prepared undoped hydridosilane oligomers with the abovementioned p-type or n-type dopants by means of a high-energy process (for example UV radiation or thermal treatment).

The proportion of the hydridosilane(s) is preferably 0.1% to 100% by weight, further preferably 1% to 50% by weight, most preferably 1% to 30% by weight, based on the total mass of the respective precursor composition. The hydridosilane may be one of the above-described hydridosilanes; it is especially neopentasilane. The rest of the formulation is composed of further constituents, i.e. particularly solvents, hydridosilane oligomers, etc.

The proportion of the hydridosilane oligomer(s) is preferably 0.1% to 100% by weight, further preferably 1% to 50% by weight, most preferably 10% to 35% by weight, based on the total mass of the respective precursor composition. The rest of the formulation is composed of further constituents, i.e. particularly solvents, hydridosilane monomers, etc.

In other embodiments, the precursor composition contains both hydridosilanes in proportions of 0.01% to 90.00% by weight and hydridosilane oligomers in proportions of 0.1% to 99.99% by weight, based in each case on the total mass of hydridosilanes and hydridosilane oligomers. In various embodiments, the precursor composition contains only hydridosilane oligomers(s) and no monomeric hydridosilanes, i.e. 100% by weight of hydridosilane oligomers based on the total mass of hydridosilanes and hydridosilane oligomers. In these embodiments, preference is given to using the hydridosilane oligomers and optionally also hydridosilanes already described above as particularly suitable.

The compositions used in the method according to the invention need not contain any solvents. However, they preferably include at least one solvent. If they contain a solvent, the proportion thereof is preferably 0.1% to 99% by weight, more preferably 25% to 95% by weight, most preferably 60% to 95% by weight, based on the total mass of the respective precursor formulation.

The proportion of the dopants in the composition may be up to about 15% by weight; typical proportions are between 1% and 5% by weight.

Solvents usable with preference for the compositions described herein are those selected from the group consisting of linear, branched and cyclic, saturated, unsaturated and aromatic hydrocarbons having 1 to 12 carbon atoms (optionally partly or fully halogenated), alcohols, ethers, carboxylic acids, esters, nitriles, amines, amides, sulphoxides and water. Particular preference is given to n-pentane, n-hexane, n-heptane, n-octane, n-decane, dodecane, cyclohexane, cyclooctane, cyclodecane, dicyclopentane, benzene, toluene, m-xylene, p-xylene, mesitylene, indane, indene, tetrahydronaphthalene, decahydronaphthalene, diethyl ether, dipropyl ether, ethylene glycol dimethyl ether, ethylene glycol diethyl ether, ethylene glycol methyl ethyl ether, diethylene glycol dimethyl ether, diethylene glycol diethyl ether, diethylene glycol methyl ethyl ether, tetrahydrofuran, p-dioxane, acetonitrile, dimethylformamide, dimethyl sulphoxide, dichloromethane and chloroform. A particularly preferred solvent is a mixture of toluene and cyclooctane.

The formulations used in accordance with the invention may additionally contain, as well as the at least one dopant, the at least one hydridosilane and the at least one hydridosilane oligomer and any solvent(s) present, also further substances, especially various additives. Corresponding substances are known to those skilled in the art.

For the method according to the invention, the semiconductor substrates used are especially silicon wafers. These may, for example, be polycrystalline or monocrystalline and may already have base doping. This base doping may be doping with an n- or p-type dopant, as already defined above.

The compositions are preferably applied via a liquid-phase method selected from printing methods (especially flexographic/gravure printing, nano- or microimprinting, inkjet printing, offset printing, reverse offset printing, digital offset printing and screenprinting) and spraying methods (pneumatic spraying, ultrasound spraying, electrospray methods). In general, suitable application methods are all known methods which enable structured coating with two different compositions without substantial overlap.

The compositions can in principle be applied over the full area (i.e. in an unstructured manner) or in a structured manner. Full-area application can especially be effected in the cases in which the first and second compositions are applied to different sides of the wafer. Particularly fine structures can be achieved by the method according to the invention if the compositions have already been applied to the substrate in a structured manner. Corresponding structured application can be achieved, for example, by the use of printing processes. Another possibility is structuring via surface pretreatment of the substrate, especially via modification of the surface tension between the substrate and the precursor-containing coating composition by a local plasma or corona treatment, and hence a local removal of chemical bonds at the substrate surface or a local conversion of the surface (e.g. Si—H termination), by chemical etchings or application of chemical compounds (especially by means of self-assembled monolayers). This achieves structuring more particularly by adhesion of the precursor-containing coating composition only to the predefined regions having favourable surface tension and/or adhesion of the dried or converted layer only to predefined regions having favourable surface tension.

Preferably, the method according to the invention, however, can be conducted by printing methods.

More preferably, the method according to the invention is conducted in such a way that the first and second composition are applied simultaneously or successively to different regions of the wafer without overlap in a structure or over the full area and the resulting coatings are converted. In the case of structured application, it is possible in this way to produce particularly fine structures having different properties.

After the application of the formulations (compositions), a precrosslinking operation can be conducted via a UV irradiation of the liquid film on the substrate, after which the still-liquid film has crosslinked precursor fractions.

After application and any precrosslinking of the formulation, the coated substrate may also preferably be dried prior to conversion, in order to remove any solvent present. Corresponding measures and conditions for this purpose are known to those skilled in the art. In order to remove exclusively volatile formulation constituents, in the case of a thermal drying operation, the heating temperature should be less than 200° C. After the application to the substrate and any subsequent precrosslinking and/or drying operation, the coating composition present on the substrate is fully converted.

The conversion step in the process according to the invention can in principle be effected by means of various methods known as such in the prior art. The conversion is effected under an inert atmosphere, especially a nitrogen atmosphere, in order to avoid conversion to SiOₓ. In general, it is possible to (a) first convert the wet film to amorphous silicon (a-Si) and then to convert the amorphous silicon to (poly)crystalline silicon (c-Si) or (b) convert the wet film directly to c-Si in one step. Preferably, the conversion is conducted thermally and/or using electromagnetic radiation and/or by electron or ion bombardment. The thermal conversion of the wet film to a-Si is preferably conducted at temperatures of 200-1000° C., preferably 300-750° C., especially preferably 400-600° C. The thermal conversion times here are preferably between 0.01 ms and 360 min. The conversion time is further preferably between 1 and 30 min, especially at a temperature of about 500° C. The conversion of the a-Si to c-Si can likewise be effected thermally, and can be conducted, for example, at temperatures of 300-1200° C., preferably 500-1100° C., especially preferably 750-1050° C. The thermal conversion times here are preferably between 30 s and 360 min. The conversion time is more preferably between 5 and 60 min, especially preferably between 10 and 30 min. The conditions specified above for the conversion of a-Si to c-Si are also suitable for the conversion of the wet film to c-Si in one step. In that case, the conversion is conducted directly at correspondingly higher temperatures or over longer periods.

Corresponding rapid high-energy processes can be effected, for example, by the use of an IR source, a laser, a hotplate, a heating probe, an oven, a flash lamp, a plasma (especially a hydrogen plasma) or a corona with suitable gas composition, an RTP system, a microwave system or an electron beam treatment (if required, in the respective preheated or warmed state).

Alternatively or additionally, conversion can be effected by irradiating with electromagnetic radiation, especially with UV light. The conversion time may preferably be between 1 s and 360 min.

Conversion is likewise possible with ion bombardment. The ions can be generated in various ways. Frequently, impact ionization, especially electron impact ionization (EI) or chemical ionization (CI), photoionization (PI), field ionization (FI), fast atom bombardment (FAB), matrix-assisted laser desorption/ionization (MALDI) and electrospray ionization (ESI) are used.

Particular preference is given to full conversion effected by thermal means, for example in an oven. The conditions for such a thermal conversion, especially in an oven, have already been described above.

A conversion in the present context is understood to mean, as already described above, conversion of the deposited precursors of the coating film formed (from the wet film) to polycrystalline semiconductor layers, either directly or via an intermediate stage of amorphous silicon. In each case, the conversion is conducted in such a way that structured polycrystalline silicon layers are the result after the conversion.

The method described for production of doped semiconductor layers on semiconductor substrates, such as silicon wafers, can additionally be conducted repeatedly—based on one wafer—either simultaneously or twice or more in succession, in which case, however, corresponding regions of the wafer surface are coated either repeatedly with the first composition or repeatedly with the second composition, but not with both compositions. The conversion of different coatings can be effected simultaneously or successively. This means that the invention covers both methods in which the first and second composition are applied simultaneously or successively, followed by the complete conversion of the regions coated both with the first and with the second composition, and methods in which the first composition is first applied and fully activated and then the second composition is applied and fully activated.

The methods described herein may further comprise, in various embodiments, a step in which the surface of the semiconductor substrate, prior to the application of the precursor composition, is provided with a dielectric layer, especially an oxide layer, most preferably a silicon oxide or aluminium oxide layer. The precursor compositions are then subsequently applied to the surface of the semiconductor substrate which has been provided with the dielectric layer. Processes for producing dielectric layers of this kind, especially oxide layers, for example SiOₓ layers, on a silicon wafer are known in the prior art. The layers are typically only a few nm in thickness; customary layer thicknesses are in the range of 1-10, especially 1-4 and more preferably about 2 nm. The dielectric layer here is sufficiently thin to allow a tunnelling effect or is locally fractured and contacts are produced at the corresponding sites (see also R. Peibst et al., “A simple model describing the symmetric IV-characteristics of p poly-crystalline Si/n mono-crystalline Si and n poly-crystalline Si/p mono-crystalline Si junctions”, IEEE Journal of Photovoltaics (2014)).

Typically, oxide layers are deposited by wet-chemical or thermal means or else by means of atomic layer deposition (see also, with regard to wet-chemical oxide: F. Feldmann et al., “Passivated Rear Contacts for high-efficiency solar cells”, Solar Energy Materials and Solar Cells (2014), and with regard to ALD layers: B. Hoex et al., “Ultralow surface recombination by atomic layer deposited Al₂O₃”, Applied Physics Letters (2006)). In various embodiments of the invention, the method according to the invention is directed to the production of highly doped polycrystalline semiconductor layers on a semiconductor substrate, especially a silicon wafer, for the production of back-contact solar cells, comprising the steps of
1. printing a liquid Si-based precursor composition containing a p-type dopant in the form of a wet film in the form of lines, in a finger structure or in the form of dots onto one side of the silicon wafer;
2. printing a liquid Si-based precursor composition containing an n-type dopant in the form of a wet film in a form complementary to the form deposited in 1. onto the same side of the silicon wafer;
3. converting the wet films to elemental polycrystalline silicon.

Step 3 can be effected in one step as described above or in two stages via the conversion of the wet film to amorphous silicon and then the conversion of the amorphous silicon to polycrystalline silicon.

In these embodiments, the process may also comprise the preceding step of deposition of an SiOₓ film of thickness about 2 nm to the reverse side (remote from the light) of a silicon wafer, in which case the liquid precursor compositions are then applied to this side in the subsequent steps. In addition, the first composition may be n-doped, for example with 2% phosphorus based on the polysilane used, and the second composition may be p-doped, for example with 2% boron based on the polysilane used. The conversion is effected, for example, in one step at 1000° C. for 20 minutes. The conversion can alternatively also be effected in two stages, as described above.

During the conversion, in addition, the SiO film is fractured locally (see R. Peibst et al., supra). The exact mechanism of current flow from the Si wafer into the polysilicon film is as yet unknown. As well as said theory of Peibst et al., the literature also describes tunnelling of the current through the SiO layer.

In all the embodiments of the invention described here in which the two compositions are applied to the same side of the wafer, the method may additionally include the step of applying a further (third) composition to the opposite side of the semiconductor substrate, i.e. especially of the wafer. This composition may likewise be in liquid form and may be applied by printing, for example in the form of a wet film. This composition may contain either n- or p-type, especially n-type, dopants. In various embodiments, this third composition is likewise a precursor composition and is as defined for the above-described first or second composition. The application, conversion, etc. can likewise be effected as described above for the first and second composition. More particularly, the corresponding conversion steps can be effected together with the conversion of the regions coated with the first and/or second composition, or separately. In various embodiments, the first and second compositions (containing n- and p-type dopants respectively) are deposited on the reverse side of the wafer, and the third composition which contains an n-type dopant and is especially likewise a precursor composition is deposited on the front side. The formulations may differ, for example, in the layer thickness and/or concentration of the dopant.

In various other embodiments of the invention, the method according to the invention is directed to the production of highly doped polycrystalline semiconductor layers on a semiconductor substrate, especially a silicon wafer, for the production of bifacial solar cells, comprising the steps of
1. printing a liquid Si-based precursor composition containing a p-type dopant in the form of a wet film onto one side of the silicon wafer;
2. converting the wet film to elemental polycrystalline silicon;
3. printing a liquid Si-based precursor composition containing an n-type dopant in the form of a wet film onto the other side of the silicon wafer;
4. converting the wet film to elemental polycrystalline silicon.

In these embodiments too, the process may also comprise the preceding step of deposition of an SiOₓ film of thickness about 2 nm to both sides of a silicon wafer, in which case the liquid precursor compositions are then applied to these oxide layers in the subsequent steps. In addition, the first composition may be n-doped, for example with 2% phosphorus based on the polysilane used, and the second composition may be p-doped, for example with 2% boron based on the polysilane used. The conversion is effected, for example, in one stage at 1000° C. for 20 minutes. Here too, step 4 can be effected in one step as described above or in two stages via the conversion of the wet film to amorphous silicon and then the conversion of the amorphous silicon to polycrystalline silicon.

The processes according to the invention have the advantage that it is possible to deposit highly doped layers directly and in a structured manner, i.e. in the desired geometry. In this case, for example, single-sided coating and/or coatings with and without overlap are possible, and the disadvantages which arise from the known CVD methods can be overcome. Direct deposition additionally has the advantage that doped silicon layers are produced in one step, whereas two or more steps are required in the processes used to date, namely the production of a silicon layer and subsequent doping by a diffusion step. It is thus possible by the processes described herein to save time and costs with respect to the known processes.

The direct incorporation of the dopants into the silicon precursor compositions also has the advantage that it is possible to use comparatively high concentrations of dopants (up to 10% in polysilane, corresponding to about 10²² cm⁻³ in polycrystalline silicon layers), and there is no limitation by diffusion.

The layers produced in this way are additionally notable for a high purity, since pure polysilicon is deposited and no possibly contaminated doped oxides are employed. Finally, subsequent removal of doped oxides, for example, is not required either.

A further advantage is that polysilanes do not contain any carbon and there is therefore no occurrence of reaction of the Si wafer with carbon and hence no formation of SiC.

The present invention also further provides the semiconductor substrates produced by the method according to the invention and for the use thereof, especially for the production of electronic or optoelectronic components, preferably solar cells. The solar cells may, for example, be back-contact solar cells.

In the production of solar cells, the semiconductor substrate produced in accordance with the invention, in a further step, can be coated with a silicon nitride layer (over a large area, especially over the whole area), and then a metal-containing composition for the production of metallic contacts, for example a silver paste, is applied to particular regions of the silicon nitride layer and burnt through by heating, in order to establish contact with the highly doped layer beneath.

Finally, the present invention also covers solar cells and solar modules comprising the semiconductor substrates produced in accordance with the invention.

The examples which follow elucidate the subject-matter of the present invention without themselves having any limiting effect.

### EXAMPLES

### Example 1

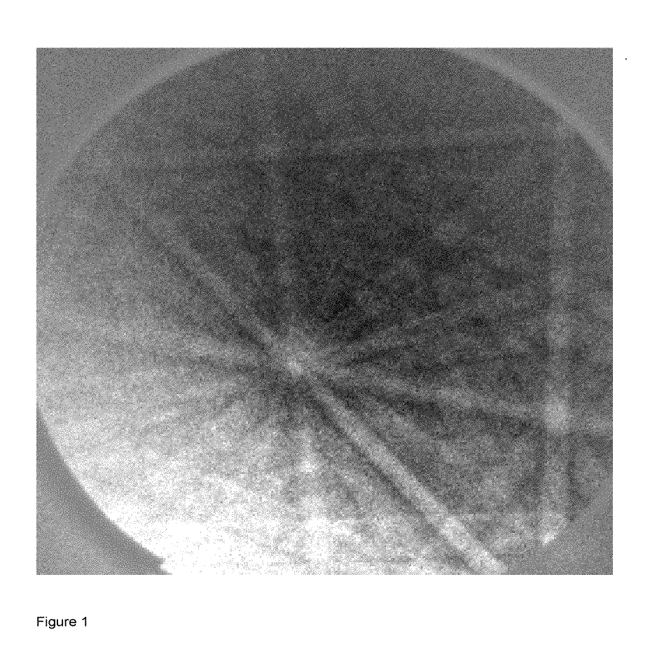

By means of spin-coating, phosphorus-doped formulations consisting of 30% neopentasilane with 1.5% phosphorus doping and 70% toluene and cyclooctane solvents were applied to both sides of an n-type silicon wafer having a resistivity of 5 ohmcm. Conversion was effected at 500° C. for 60 s to a 50 nm-thick amorphous silicon layer. In the course of thermal treatment of the phosphorus atoms at 1000° C. for 30 min, the deposited a-Si layer crystallized to crystalline silicon, as can be inferred from the diffraction image after outward diffusion in FIG. 1.

By means of spin-coating, boron-doped formulations consisting of 30% neopentasilane with 1.5% boron doping and 70% toluene and cyclooctane solvents were applied to both sides of an n-type silicon wafer having a resistivity of 5 ohm cm. Conversion was effected at 500° C. for 60 s to a 50 nm-thick amorphous silicon layer. In the course of thermal treatment of the boron atoms at 1050° C. for 60 min, the deposited a-Si layer crystallized to crystalline silicon.

### Example 2

After the deposition of polysilanes and the conversion to amorphous silicon, it was possible to crystallize the latter by means of two different methods:

1. solid-phase crystallization and

2. liquid-phase crystallization.

1: thermal annealing in a nitrogen atmosphere at temperatures above 600° C.

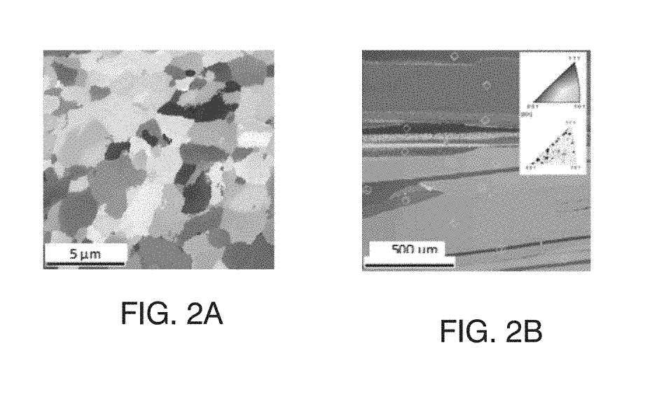

2: melting of the a-Si and subsequent liquid-based crystallization by means of an E-beam or laser. FIG. 2A shows an electron backscatter diffraction map of samples processed by means of solid-phase crystallization. FIG. 2B shows samples of a liquid-phase crystallization.

### Example 3: Production of a Back-Contact Solar Cell

A back-contact solar cell was produced as follows:

a. Single-sided patterning of a silicon wafer.

b. Deposition of a 2 nm-thick SiO film onto the planar side of the silicon wafer.

c. Inkjet printing of a liquid Si-based composition containing a p-type dopant in the form of a wet film in a finger structure to the planar side of the silicon wafer having the 2 nm-thick SiO layer. The composition contains 30% neopentasilane with 1%-10% boron doping and 70% toluene and cyclooctane solvents. The fingers typically have widths of 200 μm-1000 μm.

d. Simultaneous printing of a liquid Si-based composition containing an n-type dopant in the form of a wet film in a form complementary to the structure deposited in (a) onto the same side of the silicon wafer. The composition contains 30% neopentasilane with 1%-10% phosphorus doping and 70% toluene and cyclooctane solvents. The fingers typically have widths of 200 μm-1000 μm.

e. Converting the wet films to elemental silicon, especially amorphous silicon, by conversion. The conversion takes place under a nitrogen atmosphere at temperatures of 400-600° C. Duration: 1 s-2 minutes. Preferably 60 s at 500° C. The layer thickness of the amorphous silicon is 50-200 nm.

f. Deposition of an SiN film onto the planar reverse side.

g. Conversion of the doped a-Si layers to polycrystalline silicon at 850° C. for a duration of 30 minutes with addition of POCl₃. This results in formation of an n+ region on the patterned silicon wafer side.

h. Removal of the phosphosilicate glass (PSG) from the front side and of the SiN from the reverse side by means of HF.

i. Deposition of an antireflection layer on the front side and

j. Contacting of the p+ and n+ regions on the reverse side by means of a metal.

1: A liquid-phase method for producing a doped polycrystalline semiconductor layer on a semiconductor substrate, said method comprising:
applying a first precursor composition comprising:
(i) a first dopant; and
(ii) at least one silicon-containing precursor which is liquid under SATP conditions or at least one solvent and at least one silicon-containing precursor which is liquid or solid under SATP conditions;
to one or more regions of the surface of the semiconductor substrate, in order to create one or more region(s) of the surface of the semiconductor substrate coated with the first precursor composition;
optionally applying a second precursor composition comprising:
(i) a second dopant; and
(ii) at least one silicon-containing precursor which is liquid under SATP conditions or at least one solvent and at least one silicon-containing precursor which is liquid or solid under SATP conditions;
to one or more regions of the surface of the semiconductor substrate, in order to create one or more region(s) of the surface of the semiconductor substrate coated with the second precursor composition, where the one or more region(s) coated with the first precursor composition and the one or more region(s) coated with the second precursor composition are different and do not overlap or essentially do not overlap, and where the first dopant is an n-type dopant and the second dopant is a p-type dopant or vice versa; and
converting the silicon-containing precursor to polycrystalline silicon.

2: The method according to claim 1, wherein the first composition and/or optionally the second composition is applied to the semiconductor substrate by a printing or spraying method.

3: The method according to claim 1, wherein
(a) the at least one n-type dopant is selected from phosphorus-containing dopants, antimony-containing dopants, and mixtures of the above, and/or
(b) the at least one p-type dopant is selected from boron-containing dopants and mixtures thereof.

4: The method according to claim 1, wherein the precursor is a polysilane.

5: The method according to claim 4, wherein the precursor has the generic formula SiₙX_{c} with X=H, F, Cl, Br, I, C₁-C₁₀-alkyl, C₁-C₁₀-alkenyl, C₅-C₂₀-aryl, n≧4 and 2n≦c≦2n+2.

6: The method according to claim 4, wherein the precursor is a silicon-containing nanoparticle.

7: The method according to claim 4, wherein the precursor composition comprises at least two precursors of which at least one is a hydridosilane oligomer and at least one is an optionally branched hydridosilane of the generic formula SiₙH₂ₙ₊₂ with n=3 to 20.

8: The method according to claim 7, wherein the hydridosilane oligomer
(a) has a weight-average molecular weight of 200 to 10 000 g/mol; and/or
(b) has been obtained by oligomerization of noncyclic hydridosilanes; and/or
(c) is obtainable by thermal conversion of a composition comprising at least one noncyclic hydridosilane having not more than 20 silicon atoms in the absence of a catalyst at temperatures of less than 235° C.

9: The method according to claim 1, wherein the precursor is converted to polycrystalline silicon using electromagnetic radiation and/or electron or ion bombardment and/or by a thermal method.

10: The method according to claim 9, wherein the conversion to polycrystalline silicon is effected thermally at a temperature in the range of 300-1200° C.

11: The method according to claim 1, wherein the process further comprises the step of creating a dielectric layer on the semiconductor substrate, where the first and/or second precursor composition is subsequently applied to the dielectric layer.

12: The method according to claim 11, wherein the dielectric layer is SiOₓ or AlₓO_{y}.

13: The method according to claim 1, wherein the semiconductor substrate is a silicon wafer.

14: The method according to claim 1, wherein the first composition and the second composition are applied to the same side of the semiconductor substrate.

15: The method according to claim 1, wherein the first composition and the second composition are applied to the opposite sides of the semiconductor substrate.

16: A semiconductor substrate, produced by a method according to claim 1.

17: A method for producing a solar cell, said method comprising:
forming a doped polycrystalline semiconductor layer on said semiconductor substrate of claim 16.

18: A solar cell or solar module, comprising:
the semiconductor substrate according to claim 16.

19: The method according to claim 14, wherein the first composition and the second composition are applied to the same side of the semiconductor substrate in an interdigitated structure.
